(19) United States
(12) Patent Application Publication
(10) Pub. No.: US 2019/0148948 A1
(43) Pub. Date: May 16, 2019

(54) PHOTOVOLTAIC POWER CIRCUIT AND RESONANT CIRCUIT THEREOF

(71) Applicant: RICHTEK TECHNOLOGY CORPORATION, Zhubei City (TW)

(72) Inventor: Kuo-Chi Liu, Hsinchu (TW)

(21) Appl. No.: 16/132,365

(22) Filed: Sep. 15, 2018

(30) Foreign Application Priority Data
Nov. 14, 2017 (TW) 106139376

(51) Int. Cl. H02J 3/38; H02M 5/293; H01L 31/02

(52) U.S. Cl. CPC H02J 3/385; H02M 2005/2932; H01L 31/02021; H02M 5/293

(57) ABSTRACT

A photovoltaic power circuit includes: a photovoltaic device, a resonant circuit, and a control circuit. The photovoltaic circuit receives light to generate an input voltage. The resonant circuit is coupled to the photovoltaic device, and converts the input voltage to an output voltage to supply electrical energy to a load circuit. The resonant circuit includes a resonant inverter, a primary resonator, and a secondary resonator. The resonant inverter receives the input voltage, and operates at least one switch therein according to a control signal, to convert the input voltage to an AC resonant voltage. The control circuit adjusts a switching frequency or a duty ratio of the control signal according to an input power or an output power, based on a resonant frequency of the resonant circuit, to determine a maximum power point.

### CROSS REFERENCES

The present invention claims priority to TW 106139376 filed on Nov. 14, 2017.

### BACKGROUND OF THE INVENTION

### Field of Invention

The present invention relates to a photovoltaic power circuit and a resonant circuit thereof; particularly, it relates to a photovoltaic power circuit capable of operating in a resonant frequency. The present invention also relates to a resonant circuit for the photovoltaic power circuit.

### Description of Related Art

Prior art relevant to the present invention are U.S. Pat. Nos. 6,984,970 and 9,461,551.

In response to the energy crisis and the shortage of global energy stocks, more and more advanced countries are investing resources in researching solar cells. Solar cells belong to one kind of photovoltaic power circuits, whose the basic principle is to utilize the characteristics of a semiconductor PN junction; the junction is capable of converting solar energy it receives to electrical energy, which can be utilized to charge a battery. The V-T (voltage-current) relationship of the PN junction when it generates electrical energy is shown in FIG. 1, wherein the solid line indicates the relationship between the voltage and the current, and the dashed line indicates the product of voltage and current, that is, power. In the figure it is assumed that the received solar energy does not change, so only one curve is shown, but if the received solar energy changes, the curve will change accordingly.

As shown in FIG. 1, the maximum voltage point Voc is when the circuit is in an open-circuit condition, and the maximum current point Isc is when the circuit is in a short-circuit condition, but if a maximum power output is to be obtained, an optimal output point is located neither at the maximum voltage point nor the maximum current point, but at a Maximum Power Point (MPP) of the curve, and the corresponding voltage and the current are Vmpp and Impp, respectively. And, since the received solar energy is often not constant, a sophisticated digital circuit is required in the prior art for calculating whether the extracted electric energy is located at the Maximum Power Point (hereinafter referred to as MPP) under that condition.

An example of a prior art photovoltaic power circuit can be found in U.S. Pat. No. 6,984,970. The circuit disclosed in the present invention is substantially as shown in FIG. 2, wherein the input voltage Vin, which is generated by a photovoltaic device 2, is processed by voltage conversion through a power stage 3 to become an output voltage Vo, and power is supplied to a load 4. The load 4 can be, for example, a rechargeable battery, and the power output stage 3 can be, for example, a boost circuit, a buck circuit, an inverting circuit, or a flyback circuit, etc. In order to control the power output stage 3 to extract electrical energy at the MPP, a digital controller 5 is provided in the circuit, and a digital calculation module 51 (for example, a digital microcontroller) in the digital controller 5 continuously multiplies the input voltage Vin by the extracted current I for calculating the MPP, and the optimum voltage point Vmpp is calculated according to the MPP. The calculated optimum voltage point Vmpp is then compared with the input voltage Vin whereby a control circuit 52 generates a signal that determines how to control the power output stage 3. In the circuit shown in FIG. 2, since the voltage drop of each single PN diode junction in the photovoltaic device 2 is about 0.6V, to obtain an input voltage Vin which is sufficiently high, the photovoltaic device 2 must contain dozens of PN diodes connected in series. Typically, the photovoltaic device 2 includes 60 PN diodes connected in series to generate the input voltage Vin to be provided to the power output stage 3. When any one or more PN diodes are shielded in these PN diodes, the generated electrical power will be significantly lowered. Therefore, not only the output power efficiency of the photovoltaic power circuit is limited, but also the design difficulty is increased, and the overall cost of the circuit is accordingly increased.

In view of the above, the present invention provides a photovoltaic power circuit and a resonant circuit thereof, to overcome the drawbacks of the prior art. The photovoltaic device 2 requires only a few or even a single PN diode to convert the photovoltaic power to the electrical energy, thereby improving the application range of the photovoltaic power circuit and the resonant circuit therein.

### SUMMARY OF THE INVENTION

From one perspective, the present invention provides a photovoltaic power circuit comprising: a photovoltaic device, which is configured to receive light to generate an input voltage; a resonant circuit, which is coupled to the photovoltaic device, and is configured to convert the input voltage to an output voltage for supplying power to a load circuit; the resonant circuit including: a resonant inverter, which is coupled to the photovoltaic device, and is configured to operate at least one switch therein according to a control signal to convert the input voltage to an AC resonant voltage; a primary resonator, which is coupled to the resonant inverter, and is configured to receive the AC resonant voltage to generate a primary resonant voltage; and a secondary resonator, which is coupled to the primary resonator, and is configured to convert the primary resonant voltage to the output voltage; and a controller, which is configured to adjust a switching frequency or a duty ratio of the control signal according to an input power or an output power and based on a resonant frequency of the resonant circuit, to determine a maximum power point (MPP); wherein the resonant inverter, the primary resonator, and the secondary resonator all have the resonant frequency.

From another perspective, the present invention provides a resonant circuit for a photovoltaic power circuit, wherein the photovoltaic power circuit includes a photovoltaic device, a resonant circuit, and a controller, the photovoltaic device being configured to receive light to generate an input voltage, the resonant circuit being coupled to the photovoltaic device for converting the input voltage to an output voltage and supplying electrical energy to a load circuit, the resonant circuit comprising: a resonant inverter, which is coupled to the photovoltaic device, and is configured to receive the input voltage and operate at least one switch to convert the input voltage to an AC resonant voltage according to a control signal; a primary resonator, which is coupled to the resonant inverter, and is configured to receive the AC resonant voltage to generate a primary voltage; and a secondary resonator, which is coupled to the primary resonator, and is configured to convert the primary resonant voltage to the output voltage; wherein the controller is configured to adjust a switching frequency or a duty ratio of the control signal according to an input power or an output power and based on a resonant frequency of the resonant circuit, to determine a maximum power point (MPP); wherein the resonant inverter, the primary resonator, and the secondary resonator all have the resonant frequency.

In one preferable embodiment, the secondary resonator includes: an LC resonant circuit which is coupled to the primary resonator, and includes an inductor and a capacitor connected in series, wherein the LC resonant circuit has the resonant frequency and is configured to generate a secondary resonant voltage according to the primary resonant voltage; and a voltage booster circuit which is coupled to the LC resonant circuit, and is configured to boost the secondary resonant voltage to generate the output voltage.

In one preferable embodiment, the secondary resonator includes: an LC resonant circuit, which is coupled to the primary resonator, and includes an inductor and a capacitor connected in parallel, wherein the LC resonant circuit has the resonant frequency, and is configure to generate a secondary resonant voltage according to the primary resonant voltage; and a rectifier circuit, which is coupled to the LC resonant circuit, and is configure to rectify the secondary resonant voltage to generate the output voltage.

In one preferable embodiment, the primary resonator and the secondary resonator are coupled in a non-contact manner by electromagnetic coupling.

In one preferable embodiment, the resonant inverter circuit includes: an inverter circuit, which includes a full bridge inverter, a half bridge inverter or a Class E inverter, wherein the inverter circuit is coupled to the photovoltaic device, and the inverter circuit includes the least one switch operating according to the control signal to convert the input voltage to an AC input voltage; and an AC resonant circuit, which is coupled to the inverter circuit, and is configured to convert the AC input voltage to the AC resonant voltage.

In one preferable embodiment, the resonant circuit includes a plurality of secondary resonators and each of the secondary resonators is coupled to the primary resonator in a non-contact manner by electromagnetic coupling.

From another perspective, the present invent provides a method for extracting electrical energy from a photovoltaic device, the method comprising the following steps: operating at least one switch to convert an input voltage generated by the photovoltaic device to an AC resonant voltage according to a control signal, based on a resonant frequency; receiving the AC resonant voltage to generate a primary voltage; converting the primary voltage to an output voltage in a non-contact manner by electromagnetic coupling for supplying the electrical energy to a load circuit; and adjusting a switching frequency or a duty ratio of the control signal according to an input power or an output power to determine a maximum power point (MPP).

In one preferable embodiment, the step of converting the primary voltage to an output voltage in a non-contact manner by electromagnetic coupling for supplying electrical energy to a load circuit includes: generating a secondary resonant voltage according to the primary voltage; and generating the output voltage by boosting the secondary resonant voltage.

In one preferable embodiment, the step of converting the primary voltage to an output voltage in the non-contact manner by electromagnetic coupling for supplying the electrical energy to a load circuit includes: providing an LC resonant circuit that includes an inductor and a capacitor connected in parallel, wherein the LC resonant circuit has the resonant frequency, and generates a secondary resonant voltage according to the primary voltage; and generating the output voltage by the rectifying the secondary resonant voltage.

The objectives, technical details, features, and effects of the present invention will be better understood with regard to the detailed description of the embodiments below.

### BRIEF DESCRIPTION OF THE DRAWINGS

FIG. 1 shows a voltage-current relationship diagram of a photovoltaic device under the same received solar energy.

FIG. 2 shows a schematic circuit diagram of a photovoltaic power circuit according to prior art.

FIG. 3 shows a first embodiment of the present invention.

FIG. 4 shows a second embodiment of the present invention.

FIG. 5 shows a third embodiment of the present invention.

FIG. 6 shows a fourth embodiment of the present invention.

FIG. 7 shows a fifth embodiment of the present invention.

FIG. 8 shows a sixth embodiment of the present invention.

FIG. 9 shows a seventh embodiment of the present invention.

FIG. 10 shows a schematic diagram of the relevant signal waveforms according to the present invention.

FIG. 11 shows a schematic diagram of a primary resonator 105 and an AC resonant circuit 1033 in the second embodiment of the present invention.

### DESCRIPTION OF THE PREFERRED EMBODIMENTS

The drawings as referred to throughout the description of the present invention are for illustration only, to show the interrelations between the circuits and the signal waveforms, but not drawn according to actual scale.

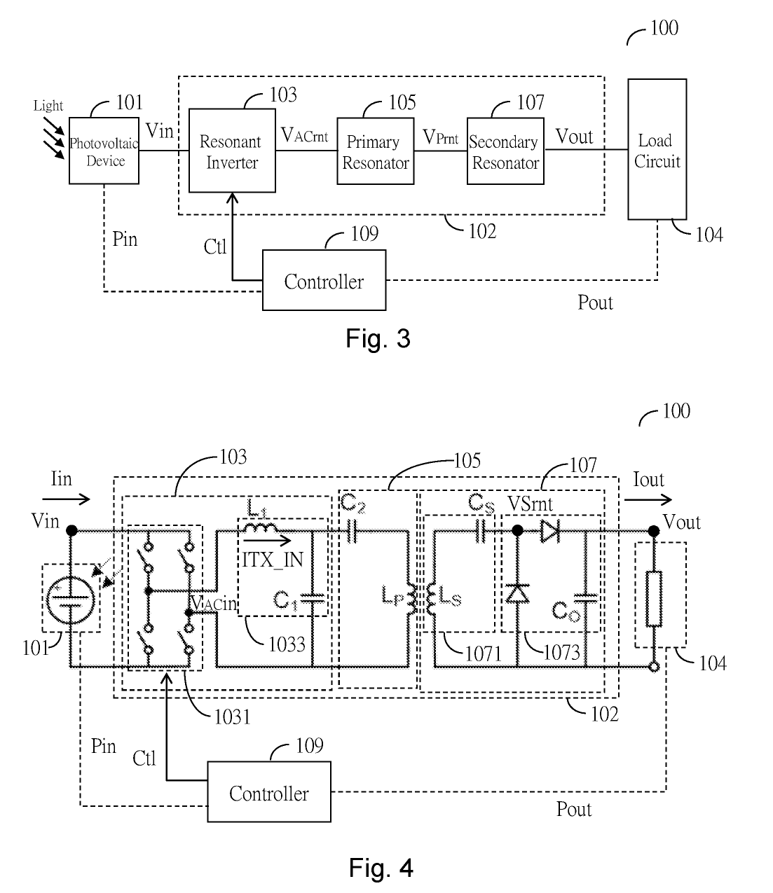

FIG. 3 shows a first embodiment of the present invention. As shown in FIG. 3, a photovoltaic power circuit 100 includes a photovoltaic device 101, a resonant circuit 102, and a controller 109. The photovoltaic device 101 is configured to receive light (as indicated by the slash arrows in the figure) to generate an input voltage Vin. The resonant circuit 102 is coupled to the photovoltaic device 101 for converting the input voltage Vin to an output voltage Vout to supply electrical energy to a load circuit 104. The load circuit 104 is, for example but not limited to, a rechargeable battery.

The resonant circuit 102 includes a resonant inverter 103, a primary resonator 105, and a secondary resonator 107. The resonant inverter 103 is coupled to the photovoltaic device 101 for receiving the input voltage Vin, and the resonant inverter 103 operates at least one switch therein to convert the DC input voltage Vin to an AC resonant voltage VACrnt according to a control signal Ctl. The primary resonator 105 is coupled to the resonant inverter 103 for receiving the AC resonant voltage VACrnt to generate a primary resonant voltage VPrnt. The secondary resonator 107 is coupled to the primary resonator 105 for converting the primary resonance voltage VPrnt to an output voltage Vout. The controller 109 adjusts a switching frequency or a duty ratio of the control signal Ctl according to an input power Pin or an output power Pout, and based on a resonant frequency of the resonant circuit 102, to determine a Maximum Power Point (MPP). The resonant inverter 103, the primary resonator 105 and the secondary resonator 107 all have a resonant frequency.

FIG. 4 shows a second embodiment of the present invention. This embodiment shows a more specific embodiment of the photovoltaic power circuit 100. As shown in the figure, the resonant inverter 103 includes an inverter circuit 1031 and an AC resonant circuit 1033. The inverter circuit 1031 converts a DC voltage to an AC voltage by means of a high frequency bridge circuit. The high frequency bridge circuit may include, for example but not limited to, a full bridge inverter as shown in the figure, which operates the switches therein according to the control signal Ctl to convert the DC input voltage Vin to an AC input voltage VACin, and the AC input voltage VACin is inputted to the AC resonant circuit 1033. In other embodiments, the inverter circuit 1031 may include, for example but not limited to, a half bridge inverter or a Class E inverter. As shown in the figure, the AC resonant circuit 1033 includes, for example but not limited to, an inductor L1 and a capacitor C1 coupled to the inverter circuit 1031, for converting the AC input voltage VACin to the AC resonant voltage VACrnt. The AC resonant circuit 1033 has a resonant frequency ω.

The primary resonator 105 is coupled to the resonant inverter 103 for receiving the AC resonant voltage VACrnt to generate a primary resonant voltage VPrnt. The primary resonator 105 has, for example but not limited to, an inductor Lp and a capacitor C2 that have the resonant frequency ω. As shown in the figure, the secondary resonator 107 is coupled to the primary resonator 105 in a non-contact manner (such as, but not limited to, electromagnetic coupling), to convert the primary resonant voltage VPrnt to the output voltage Vout that has the resonant frequency ω. As shown in the figure, the secondary resonator 107 includes an LC resonant circuit 1071 and a voltage booster circuit 1073. The LC resonant circuit 1071 is coupled to the primary resonator 105 in e.g. the electromagnetic coupling manner; the LC resonant circuit 1071 includes an inductor Ls and a capacitor Cs connected in series, and the LC resonant circuit 1071 has the resonant frequency ω. The LC resonant circuit 1071 generates a secondary resonant voltage VSrnt according to the primary resonant voltage VPrnt. The voltage booster circuit 1073 is coupled to the LC resonant circuit 1071, and in one embodiment, the is voltage booster circuit 1073 is a voltage doubler circuit which is configured to double the secondary resonant voltage VSrnt to generate the output voltage Vout. As shown in the figure, the voltage booster circuit 1073 includes, for example, two diodes and a capacitor Co to achieve the effect of doubling voltage. Note that the voltage booster circuit 1073 shown in FIG. 4 as a voltage doubler circuit is only one of the embodiments of the voltage booster circuit, and the voltage booster circuit can be embodied by many other ways; in addition, the multiple of amplification is not limited to 2 times.

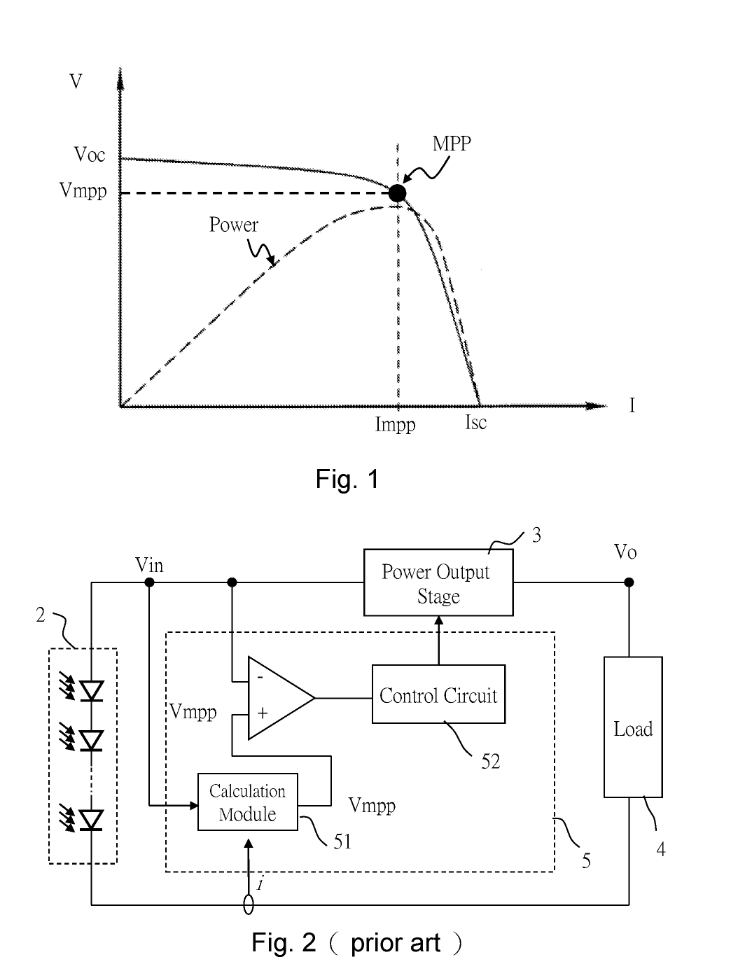

The controller 109 obtains information regarding an input power Pin by, for example but not limited to, sensing the voltage drop of the photovoltaic device 101 and the current flowing through the photovoltaic device 101, and the controller 109 calculates to determine the Maximum Power Point (MPP) and adjusts the switching frequency or the duty ratio of the control signal Ctl based on the resonant frequency ω of the resonant circuit 102 so that the switching frequency is equal to or close to the resonant frequency c. The resonant inverter 103, the primary resonator 105 and the secondary resonator 107 all have the resonant frequency ω. The MPP can be calculated and determined with reference to FIG. 1, which is well known to those of ordinary skill in the art, so the details thereof are not redundantly explained here.

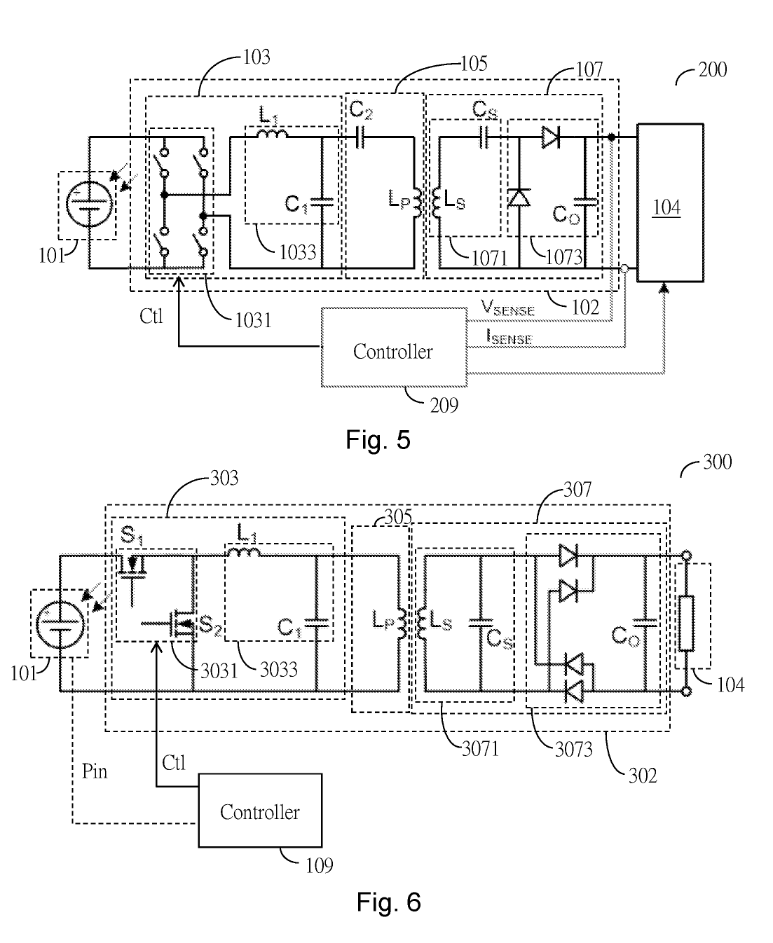

FIG. 5 shows a third embodiment of the present invention. This embodiment shows a more specific embodiment of a photovoltaic power circuit 200. The difference between this embodiment and the second embodiment is that in this embodiment, the controller 209 senses the output voltage Vout and an output current to generate a sensed voltage VSENSE and a sensed current ISENSE for calculating an output power Pout and generating a control signal Ctl accordingly. In addition, the photovoltaic power circuit 200 is operated at the MPP by

The present invention is superior to the prior art in many respects. First, for example, in the first embodiment of the present invention, the frequency of the control signal Ctl is adjusted to the resonant frequency ω of the resonant circuit 102 or close to the resonant frequency ω; as such, it is not required to connect many photovoltaic devices 101 in series, and the photovoltaic device 101 of the present invention can be composed of one single photovoltaic device (having one single PN junction), to convert the light energy power to the electrical energy, thus solving the problem in the prior art that the efficiency of converting the photovoltaic power to the electrical energy is greatly reduced when any one of the photovoltaic devices is shielded.

Second, according to the present invention, in the resonant circuit 102, the primary resonator 105 and the secondary resonator 107 are electromagnetically coupled with each other in a non-contact manner, that is, the photovoltaic device 101, the resonant inverter 103 and the primary resonator 105 (and the controller 109), are on the same side, while the resonator 107 and the load circuit 104 are on the other side, so the circuits on two sides are not directly connected, and in this way, the circuits on the same side as the photovoltaic device 101 (for example, circuits belonging to the solar panel circuit and its periphery), and the circuits on the same side as the resonator 107 and the load circuit 104 (for example, circuits belonging to the rechargeable battery circuit and its periphery) can be separated and isolated from each other, and the battery is charged by a wireless manner, providing more flexibility in application.

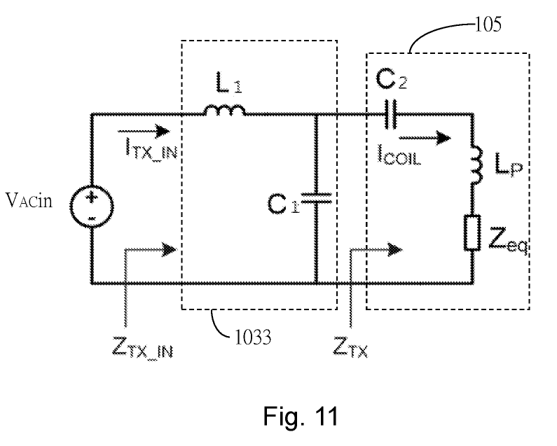

Further, by resonance operation in the present invention, the current flowing through the coil (inductor LP) of the primary resonator 105 can be maintained at a constant current regardless of whether the load circuit 104 is heavily loaded or lightly loaded. In detail, referring to FIG. 11, there is shown a schematic diagram of the primary resonator 105 and an AC resonant circuit 1033 in accordance with the second embodiment of the present invention. As shown in the figure, assuming a total equivalent impedance behind the inverter circuit 1031 being ZTX_IN (“behind” can be understood as, seeing from the inverter circuit 1031 along the arrow direction), a current flowing through the inductor L1 being ITX_IN, a total equivalent impedance behind the AC resonant circuit 1033 being ZTX, a current flowing through the inductor LP being ICOIL, and a reflection impedance behind the primary resonator 105 being Zeq,

when

$$w L 1 = \frac{1}{w C 1} = X 1$$

and ZTX=jXP+Zeq, wherein XP is an equivalent impedance of the inductor LP, an equivalent impedance is:

$$ZTX\_IN = j X 1 + \frac{ZTX \times ( - j X 1 )}{ZTX - j X 1} = \frac{{X}_{1}^{2}}{Zeq + j XP - j X 1} ,$$

and a current ICOIL flowing through the impedance LP is:

$$ICOIL = \frac{VAC in}{ZTX\_IN} \times \frac{( - j X 1 )}{j XP + Z eq - j X 1} = \frac{- j VAC in}{X 1} .$$

Thus, the reflected impedance Zeq behind the primary resonator 105 is independent of the current ICOIL flowing through the impedance LP, and in the case where the AC input voltage VACin does not change much, the current ICOIL flowing through the coil (inductor LP) of the primary resonator 105 can be maintained at a constant current.

FIG. 6 shows a fourth embodiment of the present invention. This embodiment shows a more specific embodiment of a photovoltaic power circuit 300. As shown in the figure, the resonant inverter 303 includes an inverter circuit 3031 and an AC resonant circuit 3033. The inverter circuit 3031 converts the DC voltage to the AC voltage by means of a high frequency bridge circuit, which is, for example but not limited to, a half bridge inverter including switches S1 and S2 as shown in the figure, and the inverter circuit 3031 operates the switches S1 and S2 according to the control signal Ctl to convert the DC input voltage Vin to the AC input voltage VACin. As shown in the figure, the AC resonant circuit 3033 includes, for example but not limited to, an inductor L1 and a capacitor C1 coupled to the inverter circuit 3031 for converting the AC input voltage VACin to the AC resonant voltage VACrnt. The AC resonant circuit 3033 has a resonant frequency ω.

A primary resonator 305 is coupled to the resonant inverter 303 for receiving the AC resonant voltage VACrnt to generate a primary resonant voltage VPrnt. The primary resonator 305 includes, for example but not limited to, an inductance Lp, which has a resonant frequency ω with a capacitor C1 in the AC resonant circuit 3033. As shown in the figure, a secondary resonator 307 is coupled to the primary resonator 305 in a non-contact manner (such as but not limited to electromagnetic coupling), for converting the primary resonant voltage VPrnt to the output voltage Vout that has the resonant frequency ω. As shown in the figure, the secondary resonator 307 includes an LC resonant circuit 3071 and a rectifier circuit 3073. The LC resonant circuit 3071, which is coupled to the primary resonator 305 by electromagnetic coupling, includes an inductor Ls and a capacitor Cs connected in parallel, and the LC resonant circuit 3071 has a resonant frequency ω. The LC resonant circuit 3071 generates a secondary resonance voltage VSrnt according to the primary resonant voltage VPrnt. The inductance Ls and the capacitor Cs coupled in parallel provide a voltage booster effect, and the secondary resonance voltage VSrnt can be further raised as compared with the second embodiment. The rectifier circuit 3073 is coupled to the LC resonant circuit 3071 for rectifying the secondary resonance voltage VSrnt to generate the output voltage Vout. As shown in the figure, the rectifier circuit 3073 includes, for example, four diodes and a capacitor Co, wherein the four diodes are connected as a full bridge rectifier circuit. Note that the rectifier circuit 3073 shown in FIG. 6 is only one of the embodiments of the rectifier circuits, and the rectifier circuit 3073 may be embodied in many other forms, which is well known to a person having ordinary skill in the art, so the details thereof are not redundantly explained here.

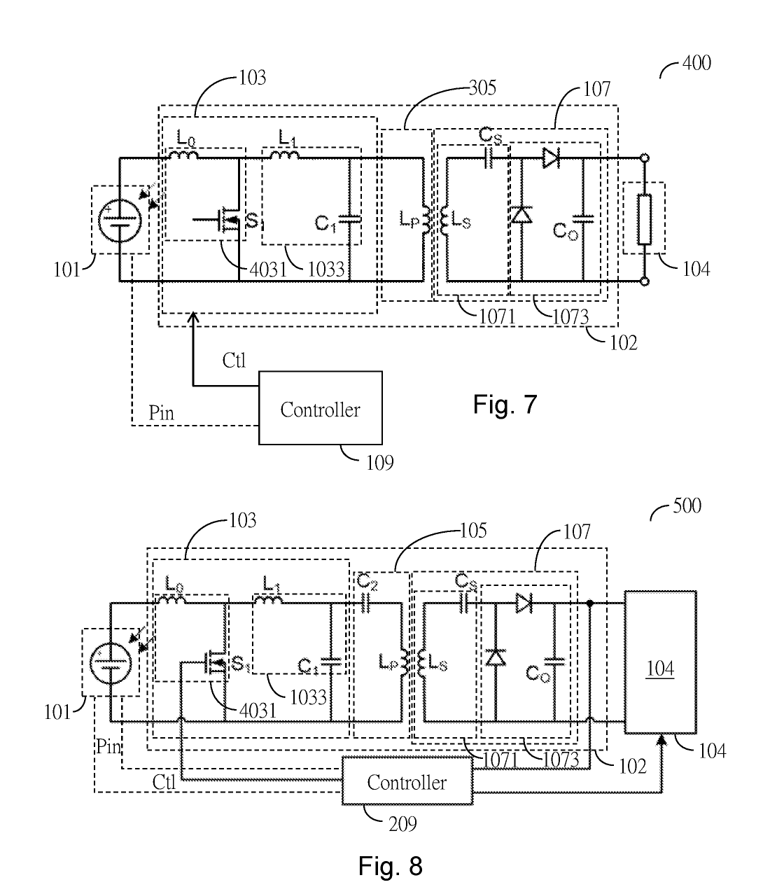

FIG. 7 shows a fifth embodiment of the present invention. This embodiment shows a more specific embodiment of a photovoltaic power circuit 400. This embodiment differs from the second embodiment in that, first, the same primary resonator 305 as that of the third embodiment is employed. Second, in the present embodiment, the inverter circuit 4031 is embodied as a high frequency bridge circuit to convert the DC voltage to the AC voltage, which includes, for example but not limited to, a class E inverter including a switch S1 and an inductor L0 as shown in the figure, and the switch S1 is operated according to the control signal Ctl to convert a DC input voltage Vin to an AC input voltage VACin that is input to the AC resonant circuit 1033.

FIG. 8 shows a sixth embodiment of the present invention. This embodiment shows a more specific embodiment of a photovoltaic power circuit 500. This embodiment is different from the fifth embodiment in that the present embodiment employs the same controller 209 as the third embodiment. The controller 209 senses the output voltage Vout and the output current to generate the sensed voltage VSENSE and the sensed current ISENSE for calculating an output power Pout and generating the control signal Ctl accordingly. In addition, the photovoltaic power circuit 500 is operated at MPP by adjusting the current flowing through the load circuit 104.

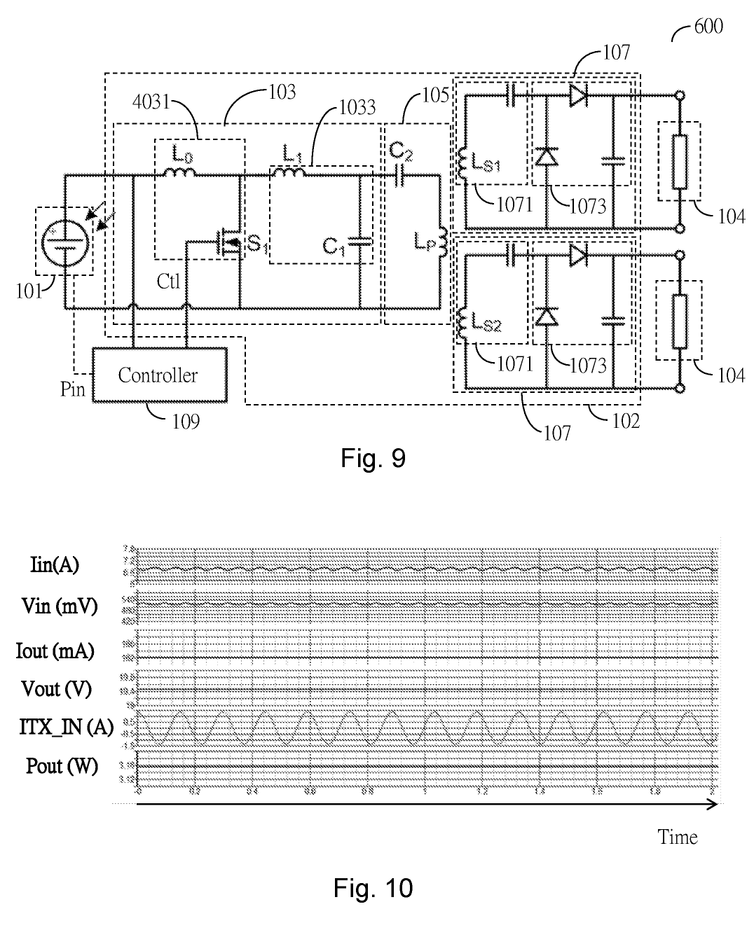

FIG. 9 shows a seventh embodiment of the present invention. This embodiment shows a more specific embodiment of a photovoltaic power circuit 600. This embodiment differs from the fifth embodiment in that the photovoltaic power circuit 600 of the present embodiment has plural (for example but not limited to, two) secondary resonators 107. That the primary resonator can be coupled to more than one secondary resonators is also an advantage of the present invention superior to the prior art. In the present invention, the primary resonator and the secondary resonators may be coupled by electromagnetic coupling, and therefore, the primary resonator may be directly coupled to plural secondary resonators without other additional circuits.

FIG. 10 shows a schematic diagram of the signal waveforms in accordance with the present invention. Please refer to FIG. 10 in conjunction with FIG. 4, wherein FIG. 10 shows the signal waveforms of an input current fin, an input voltage Vin, an output current Iout, an output voltage Vout, and a current ITX_IN flowing through the photovoltaic device 101. According to one embodiment of the present invention, the input voltage Vin is about 0.5V, and the output voltage Vout is about 19.5V, so the conversion rate is about 39 times, which is excellent.

The present invention has been described in considerable detail with reference to certain preferred embodiments thereof. It should be understood that the description is for illustrative purpose, not for limiting the scope of the present invention. The various embodiments described above are not limited to being used alone; two embodiments may be used in combination, or a part of one embodiment may be used in another embodiment. As an example, the plural secondary resonators shown in FIG. 9 are also applicable to other embodiments. In the context of the present invention, to perform an action “according to” a certain signal is not limited to performing an action strictly according to the signal itself, but can be performing an action according to a converted form or a scaled-up or down form of the signal, i.e., the signal can be processed by a voltage-to-current conversion, a current-to-voltage conversion, and/or a ratio conversion, etc. before an action is performed. Therefore, in the same spirit of the present invention, those skilled in the art can think of various equivalent variations and various combinations, and the scope of the present invention should include all such variations.

What is claimed is:

1. A photovoltaic power circuit comprising:
a photovoltaic device, which is configured to receive light to generate an input voltage;
a resonant circuit, which is coupled to the photovoltaic device, and is configured to convert the input voltage to an output voltage for supplying power to a load circuit; the resonant circuit including:
a resonant inverter, which is coupled to the photovoltaic device, and is configured to operate at least one switch therein according to a control signal to convert the input voltage to an AC resonant voltage;
a primary resonator, which is coupled to the resonant inverter, and is configured to receive the AC resonant voltage to generate a primary resonant voltage; and
a secondary resonator, which is coupled to the primary resonator, and is configured to convert the primary resonant voltage to the output voltage; and
a controller, which is configured to adjust a switching frequency or a duty ratio of the control signal according to an input power or an output power and based on a resonant frequency of the resonant circuit, to determine a maximum power point (MPP);
wherein the resonant inverter, the primary resonator, and the secondary resonator all have the resonant frequency.

2. The photovoltaic power circuit of claim 1, wherein the secondary resonator includes:
an LC resonant circuit, which is coupled to the primary resonator, and includes an inductor and a capacitor connected in series, wherein the LC resonant circuit has the resonant frequency and is configured to generate a secondary resonant voltage according to the primary resonant voltage; and
a voltage booster circuit, which is coupled to the LC resonant circuit, and is configured to boost the secondary resonant voltage to generate the output voltage.

3. The photovoltaic power circuit of claim 1, wherein the secondary resonator includes:
an LC resonant circuit, which is coupled to the primary resonator, and includes an inductor and a capacitor connected in parallel, wherein the LC resonant circuit has the resonant frequency, and is configure to generate a secondary resonant voltage according to the primary resonant voltage; and
a rectifier circuit, which is coupled to the LC resonant circuit, and is configure to rectify the secondary resonant voltage to generate the output voltage.

4. The photovoltaic power circuit of claim 1, wherein the primary resonator and the secondary resonator are coupled in a non-contact manner by electromagnetic coupling.

5. The photovoltaic power circuit of claim 1, wherein the resonant inverter circuit includes:
an inverter circuit, which includes a full bridge inverter, a half bridge inverter or a Class E inverter, wherein the inverter circuit is coupled to the photovoltaic device, and the inverter circuit includes the least one switch operating according to the control signal to convert the input voltage to an AC input voltage; and
an AC resonant circuit, which is coupled to the inverter circuit, and is configured to convert the AC input voltage to the AC resonant voltage.

6. The photovoltaic power circuit of claim 1, wherein the resonant circuit includes a plurality of secondary resonators and each of the secondary resonators is coupled to the primary resonator in a non-contact manner by electromagnetic coupling.

7. A resonant circuit for a photovoltaic power circuit, wherein the photovoltaic power circuit includes a photovoltaic device, a resonant circuit, and a controller, the photovoltaic device being configured to receive light to generate an input voltage, the resonant circuit being coupled to the photovoltaic device for converting the input voltage to an output voltage and supplying electrical energy to a load circuit, the resonant circuit comprising:
a resonant inverter, which is coupled to the photovoltaic device, and is configured to receive the input voltage and operate at least one switch to convert the input voltage to an AC resonant voltage according to a control signal;
a primary resonator, which is coupled to the resonant inverter, and is configured to receive the AC resonant voltage to generate a primary voltage; and
a secondary resonator, which is coupled to the primary resonator, and is configured to convert the primary resonant voltage to the output voltage;
wherein the controller is configured to adjust a switching frequency or a duty ratio of the control signal according to an input power or an output power and based on a resonant frequency of the resonant circuit, to determine a maximum power point (MPP);
wherein the resonant inverter, the primary resonator, and the secondary resonator all have the resonant frequency.

8. The resonant circuit of claim 7, wherein the secondary resonator includes:
an LC resonant circuit, which is coupled to the primary resonator, and includes an inductor and a capacitor connected in series, wherein the LC resonant circuit has the resonant frequency and is configured to generate a secondary resonant voltage according to the primary resonant voltage; and
a voltage booster circuit, which is coupled to the LC resonant circuit, and is configured to boost the secondary resonant voltage to generate the output voltage.

9. The resonant circuit of claim 7, wherein the secondary resonator includes:
an LC resonant circuit, which is coupled to the primary resonator, and includes an inductor and a capacitor connected in parallel, wherein the LC resonant circuit has the resonant frequency, and is configure to generate a secondary resonant voltage according to the primary resonant voltage; and
a rectifier circuit, which is coupled to the LC resonant circuit, and is configure to rectify the secondary resonant voltage to generate the output voltage.

10. The resonant circuit of claim 7, wherein the primary resonator is coupled to the secondary resonator in a non-contact manner by electromagnetic coupling.

11. The resonant circuit of claim 7, wherein the resonant inverter includes:
an inverter circuit, which includes a full bridge inverter, a half bridge inverter or a Class E inverter, wherein the inverter circuit is coupled to the photovoltaic device, and the inverter circuit includes the least one switch operating according to the control signal to convert the input voltage to an AC input voltage; and
an AC resonant circuit, which is coupled to the inverter circuit, and is configured to convert the AC input voltage to the AC resonant voltage.

12. The resonant circuit of claim 7, wherein the resonant circuit includes a plurality of secondary resonators and each of the secondary resonators is coupled to the primary resonator in a non-contact manner by electromagnetic coupling.

13. A method for extracting electrical energy from a photovoltaic device, the method comprising the following steps:
operating at least one switch to convert an input voltage generated by the photovoltaic device to an AC resonant voltage according to a control signal, based on a resonant frequency;
receiving the AC resonant voltage to generate a primary voltage;
converting the primary voltage to an output voltage in a non-contact manner by electromagnetic coupling for supplying the electrical energy to a load circuit; and
adjusting a switching frequency or a duty ratio of the control signal according to an input power or an output power to determine a maximum power point (MPP).

14. The method of claim 13, wherein the step of converting the primary voltage to an output voltage in a non-contact manner by electromagnetic coupling for supplying electrical energy to a load circuit includes:
generating a secondary resonant voltage according to the primary voltage; and
generating the output voltage by boosting the secondary resonant voltage.

15. The method of claim 13, wherein the step of converting the primary voltage to an output voltage in the non-contact manner by electromagnetic coupling for supplying the electrical energy to a load circuit includes:
providing an LC resonant circuit that includes an inductor and a capacitor connected in parallel, wherein the LC resonant circuit has the resonant frequency, and generates a secondary resonant voltage according to the primary voltage; and
generating the output voltage by the rectifying the secondary resonant voltage.
